(19) United States
(12) Patent Application Publication
(10) Pub. No.: US 2021/0263706 A1
(43) Pub. Date: Aug. 26, 2021

(54) PROCESSING RADAR SIGNALS

(71) Applicant: Infineon Technologies AG, Neubiberg (DE)

(72) Inventors: Andre Roger, Muenchen (DE); Markus Bichl, Feldkirchen-Westerham (DE); Dian Tresna Nugraha, Bandung (ID); Romain Ygnace, Brunnthal (DE)

(21) Appl. No.: 17/179,886

(22) Filed: Feb. 19, 2021

(30) Foreign Application Priority Data
Feb. 21, 2020 (DE) 10 2020 104 594.8

(51) Int. Cl. G06F 7/483; G01S 7/288; G01S 7/41; G06F 7/48

(52) U.S. Cl. CPC G06F 7/483; G01S 7/288; G01S 2007/2883; G06F 7/4824; G01S 7/418

(57) ABSTRACT

A radar device is configured to: select a set of operands comprising several operands, determine a common exponent for the operands of the set of operands, normalize the operands based on the common exponent, compress each operand by reducing the resolution of its mantissa, and store the common exponent and the compressed operands in a memory. Also, a vehicle including such radar device and an according method as well as computer program product are provided.

### REFERENCE TO RELATED APPLICATION

This application claims priority to German Application No. 10 2020 104 594.8, filed on Feb. 21, 2020, the contents of which are hereby incorporated by reference in their entirety.

### FIELD

Embodiments of the present disclosure relate to radar applications, in particular an efficient way to process radar signals obtained by at least one radar sensor, e.g., via at least one antenna. Processing radar signals in this regard in particular refers to radar signals received by a sensor or an antenna.

### BACKGROUND

Several radar variants may be used in cars for various applications. For example, radar can be used for blind spot detection (parking assistant, pedestrian protection, cross traffic), collision mitigation, lane change assist and adaptive cruise control. Numerous use case scenarios for radar appliances may be directed to different directions (e.g., back, side, front), varying angles (e.g., azimuth direction angle) and/or different distances (short, medium or long range). For example, an adaptive cruise control may utilize an azimuth direction angle amounting to ±18 degrees, the radar signal is emitted from the front of the car, which allows a detection range up to several hundred meters.

A radar source emits a signal and a sensor detects a returned signal. A frequency shift between the emitted signal and the detected signal (based on, e.g., a moving car emitting the radar signal) can be used to obtain information based on the reflection of the emitted signal. Front-end processing of the signal obtained by the sensor may comprise a Fast Fourier Transform (FFT), which may result in a signal spectrum, i.e. a signal distributed across frequency. The amplitude of the signal may indicate an amount of echo, wherein a peak may represent a target that needs to be detected and used for further processing, e.g., adjust the speed of the car based on another car travelling in front.

A radar processing device may provide different types of outputs, e.g., a command to a control unit, an object or an object list to be post-processed by at least one control unit, or at least one FFT peak to be post-processed by at least one control unit. Utilizing FFT peaks enables high performance post processing.

US 2016 0033631 A1 describes radar data compression that reduces the amount of data that needs to be accumulated between a Range FFT and a Doppler FFT in a radar system using a Fast Chirp Waveform.

### SUMMARY

The disclosure is directed to an improvement in existing solutions and in particular to efficiently process signals in a radar system that may eventually lead to an improved target recognition.

This problem is solved according to the features of the present disclosure.

The examples suggested herein may in particular be based on at least one of the following solutions. In particular, combinations of the following features could be utilized in order to reach a desired result. The features of the method could be combined with any feature(s) of the device, apparatus or system or vice versa.

A radar device is provided that is arranged for conducting the following acts:

selecting a set of operands comprising several operands,

determining a common exponent for the operands of the set of operands,

normalizing the operands based on the common exponent,

compressing each operand by reducing the resolution of its mantissa, and

storing the common exponent and the compressed operands in a memory.

According to an embodiment, the operands are operands supplied by an FFT operation.

An FFT unit may be provided as part of the radar device or external to the radar device. The FFT unit may supply FFT results, which are used as operands.

In one embodiment, the FFT operation may be a 1st stage FFT, a 2nd stage FFT or a 3rd stage FFT operation that is conducted based on signals obtained (detected and sampled) by radar device.

According to an embodiment, several sets of operands are processed until all operands have been compressed and stored in the memory.

According to an embodiment, the set of operands is compressed to a predetermined block size.

In one embodiment, the block size may be 64 bits, 128 bits or any multiple thereof.

According to an embodiment, the operands of the set of operands are floating-point numbers comprising a sign, an exponent and a mantissa.

According to an embodiment, the operands of the set of operands are compressed utilizing one resolution of a mantissa.

According to an embodiment, the operands of the set of operands are compressed utilizing at least two resolutions provided by at least two mantissas of reduced size compared to resolution of the mantissa of the non-compressed operands.

According to an embodiment, the common exponent is determined based on the set of operands.

According to an embodiment, the common exponent is determined based on the largest exponent within the set of operands.

According to an embodiment, the common exponent is determined based on the set of operands and at least one additional value, offset or constant.

A vehicle is suggested comprising at least one radar device as described herein.

Further, a method is provided for processing radar signals comprising:

selecting a set of operands comprising several operands,

determining a common exponent for the operands of the set of operands,

normalizing the operands based on the common exponent,

compressing each operand by reducing the resolution of its mantissa, and

storing the common exponent and compressed operands in a memory.

Also, a computer program product is suggested, which is directly loadable into a memory of a digital processing device, comprising software code portions for performing the acts of the method as described herein.

### BRIEF DESCRIPTION OF THE DRAWINGS

Embodiments are shown and illustrated with reference to the drawings. The drawings serve to illustrate the basic principle, so that only aspects necessary for understanding the basic principle are illustrated. The drawings are not to scale. In the drawings the same reference characters denote like features.

FIG. 1 shows an example diagram comprising steps to obtain and store compressed radar data;

FIG. 2 shows an example diagram of an alternative approach to obtain and store compressed radar data;

FIG. 3 shows a table to visualize the compression scheme as suggested in FIG. 1;

FIG. 4 shows a table comprising the values “mantissa12” (see column 8 of FIG. 3), “mantissa7” (see column 9 of FIG. 3) and “mantissa8” for the operands 1 to 8.

### DETAILED DESCRIPTION

The approach described herein suggests utilizing data compression of values in floating point representation that may be used in radar processing applications. Compressing data before it is stored in a memory bears the advantage that existing memory may be used more efficiently or that less memory space may suffice.

A suitable data format may be floating point, which may be subject to such compression. Radar systems may utilize an operand format of, e.g., 8 bits or 16 bits.

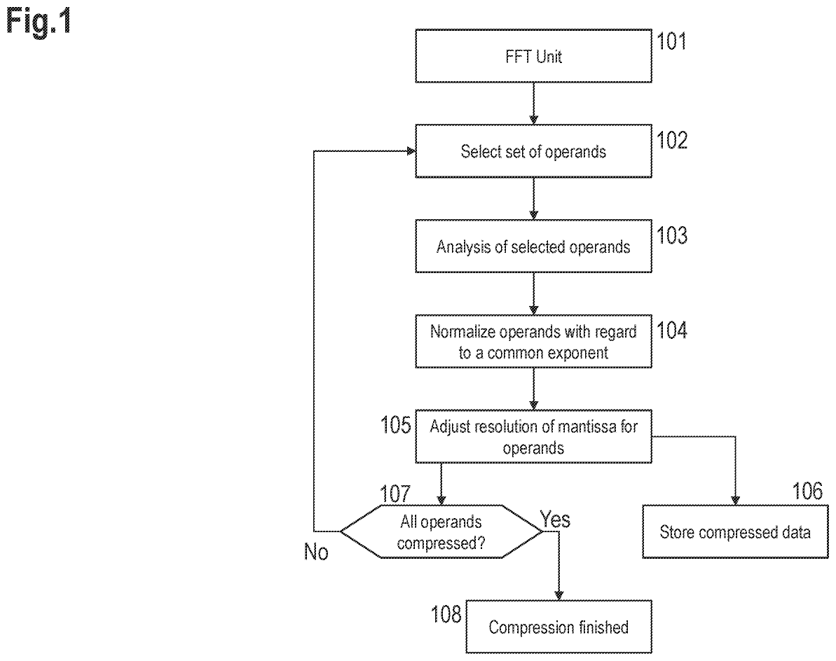

FIG. 1 shows an example diagram comprising acts to obtain and store compressed radar data. An FFT unit 101 provides FFT results. A set (or selection) of operands of the FFT results is determined in a subsequent act 102. Next, at 103, the operands are analyzed and at 104 the operands are normalized and a shared or common exponent is determined to be used for all operands. In a subsequent act 105, the resolution of the mantissa of the operands is adjusted and the compressed data are stored at 106.

At 107 it is checked whether all operands have been compressed. If this is true (YES), the compression has reached its end (see act 108). If it is not true (NO) and additional operands need to be compressed, it is branched to act 102. Hence, several sets of operands may be compressed utilizing the compression scheme according to acts 103 to 105 and storing the compressed set of operands at 106.

Hence, after an FFT stage (it may be a first, second or third stage FFT), FFT results are compressed based on at least one set of operands.

The operand may in particular be a real or complex representation or it may be the real number or the imaginary number of the selected operand.

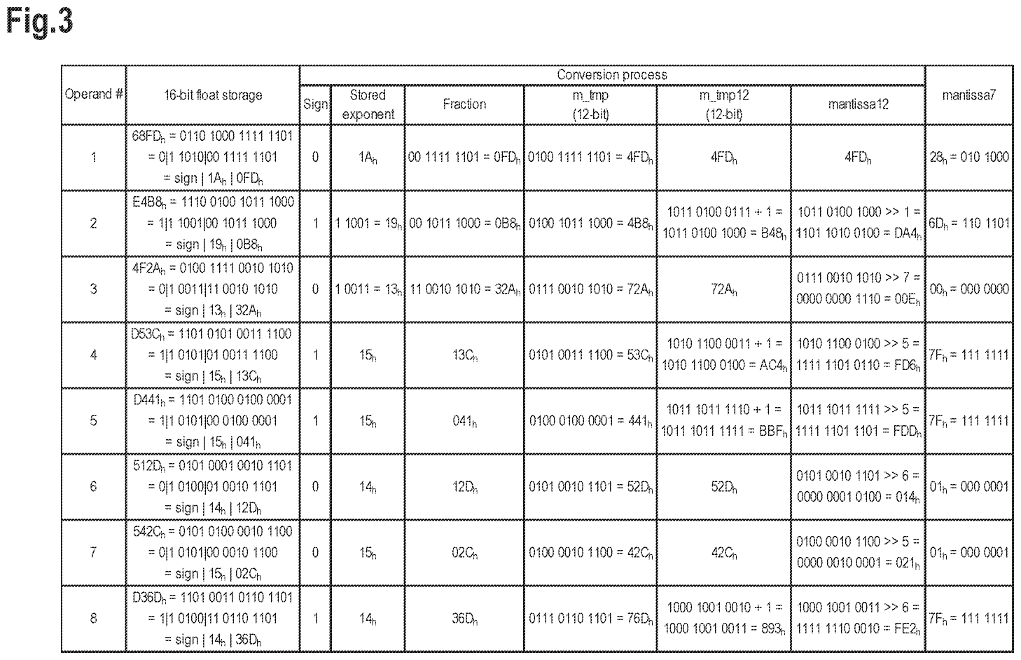

FIG. 3 shows a table to visualize one example of the compression scheme as suggested in FIG. 1. It is noted that this is not a mandatory solution for any kind of implementation. It is used to explain and visualize the acts conducted to achieve the compression.

The first column “Operand #” indicates the number of an operand. In this example, eight operands are shown referenced by numerals 1 to 8. Here, the eight operands constitute the example set of operands.

The second column “16-bit float storage” shows the 16-bit representation of the operand comprising

a first sign bit (see also third column);

the subsequent 5 bits represent the exponent (see also fourth column); and

the remaining 10 bits represent the fraction (see also fifth column).

The subscripted character “h” indicates that it is a hexadecimal value. Also, the binary representation of the 16-bit float storage operand is visualized in the second column.

The sixth column shows a temporary value “m_tmp”, the seventh column shows a temporary value “m_tmp12”, the eighth column shows a mantissa “mantissa12” and the ninth column shows a compressed mantissa “mantissa7”. The sixth column up to the eighth column are used to explain the conversion process in more detail.

The compressed mantissa “mantissa7” is determined by conducting the following acts:

(1) Determine the highest value of any of the operands 1 to 8 based on the operand's exponent shown in the fourth column. In this example, operand 1 has the largest exponent 1Ah, which is chosen as common exponent.

(2) Determine the temporary value “m_tmp” by extending the MSBs (most significant bits, i.e. the bits on the left) of the binary representation of the fraction by the two bits “01” (append the two bits “01” to the left of the value of the fraction).

With regard to operand 2, the 10-bit representation of the fraction is extended to obtain a 12-bit representation “m_tmp” as follows:

00 1011 1000→0100 1011 1000

(3) Determine the temporary value “m_tmp12” by building the 2s complement in case the sign is 1. If the sign is 0, m_tmp12 equals m_tmp.

The 2s complement is determined by (i) inverting the bits of m_tmp and (ii) adding 1. This is shown as an example in FIG. 3 for the operands 2, 4, 5 and 8.

(4) The “mantissa12” value is determined by “sign-extended-right-shifting” the “m_tmp12” value dependent on the value of the sign and dependent on the difference between the common exponent and the actual exponent.

For operand 2 the following applies: The common exponent amounts to 1Aₕ (=2610) and the exponent of the operand 2 is 19ₕ (=2510). Hence the difference between the exponents amounts to 1. The “sign-extended-right-shifting” comprises a right shift of the “m_tmp”-value by one bit, filling the left-hand side of the bits with the value of the sign—which for operand 2 is 1.

Another example is operand 3: The difference between the common exponent and the exponent of operand 3 amounts to 7. As the sign of operand 3 is 0, seven 0-values are entered at the left-hand side and the value of “m_tmp12” is right-shifted by 7 bits.

The results of the “sign-extended-right-shifting” are visualized in the eighth column of the table shown in FIG. 3.

(5) The value of “mantissa7” is determined based on the “mantissa12” as follows: The 7 MSBs of the mantissa12 are taken and the 8th MSB of the mantissa12 value determines if a rounding is applied: If the 8th MSB is 1, the value 1 is added and if the 8th MSB is 0, nothing is added.

In other words, if the 8th MSB of mantissa12 is 0, the value of mantissa7 is obtained by extracting the 7 MSBs from the mantissa12. This applies for operands 2, 3, 7 and 8.

If the 8th MSB of mantissa12 is 1, the value of mantissa7 is obtained by extracting the 7 MSBs from the mantissa12 and adding the binary value 1. This applies for operands 1, 4, 5 and 6.

Hence, a block of compressed data can be determined by concatenating the bits of the common exponent (1Aₕ) with the bits of the mantissa7 for all operands 1 to 8, which results in the following bits:

### 11010 0101000 1101101 0000000 1111111 1111111 0000001 0000001 1111111 XXX,

wherein “X” indicates an additional (arbitrary) bit. In this example, three such “X”-bits are added to fill up a block of 64 bits.

This representation can be re-sorted in 4-bit portions as follows

1101 0010 1000 1101 1010 0000 0011 1111

1111 1111 0000 0010 0000 0111 1111 1XXX,

which in hexadecimal notation corresponds to

D28D A03F FF02 07F8.

The 16-bit floating point representation shown in the second column of the table of FIG. 3 require eight times 16 bits, i.e. 128 bits of memory space, wherein the compressed representation only requires four times 16 bits, i.e. 64 bits of memory space.

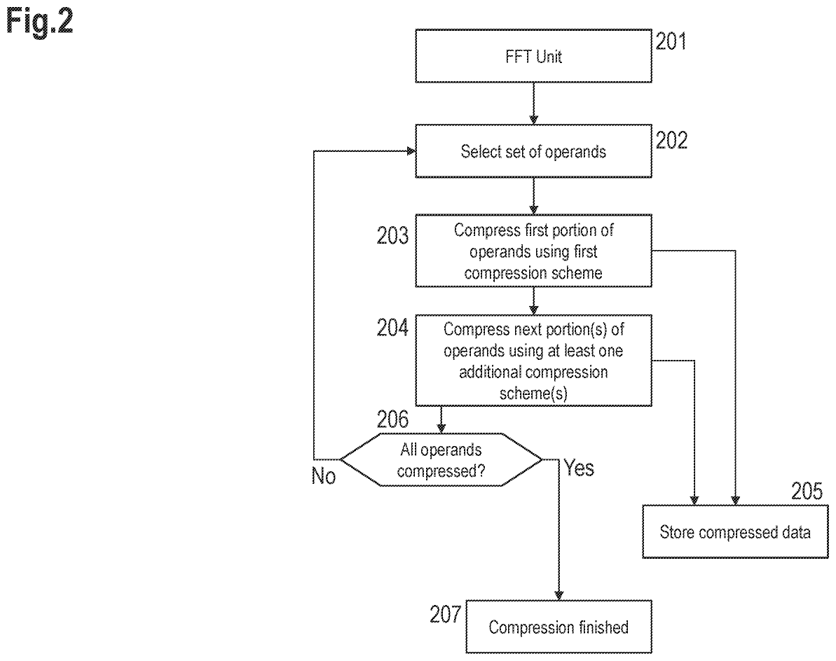

FIG. 2 shows an example diagram of an alternative approach to obtain and store compressed radar data. An FFT unit 201 provides FFT results. A set (or selection) of operands of the FFT results is determined in a subsequent act 202. Next, at step 203, a first portion of the operands is compressed by using a first compression scheme. In a subsequent act 204, at least one remaining portion of operands is compressed using at least one additional compression scheme.

Subsequent to each of acts 203 and 204, the respective compressed data are stored at 205.

At 206—subsequent to the act 204—it is checked whether all operands have been compressed. If this is true (YES), the compression has reached its end (see act 207). If it is not true (NO) and additional operands need to be compressed, it is branched to the step 202.

Hence, the alternative embodiment pursuant to FIG. 2 suggests combining different compression schemes instead of a single compression. This allows flexibly allocating bits to efficiently utilize given block sizes (e.g., of 64 bits). In particular, the sizes of the mantissas may vary for different compression schemes.

Based on the example explained with regard to FIG. 3 above, the three unused bits referred to as “X” can be efficiently utilized by providing an 8-bit mantissa “mantissa8” for three operands instead of the 7-bit mantissa “mantissa7”.

Hence, a variable precision coding can be applied with some operands being stored with higher precision than other operands. Based on the example shown above, the operands 1, 3, 5, 7 and 8 may utilize the lower precision mantissa “mantissa7” and the operands 2, 4 and 6 may utilize the higher precision mantissa “mantissa8”.

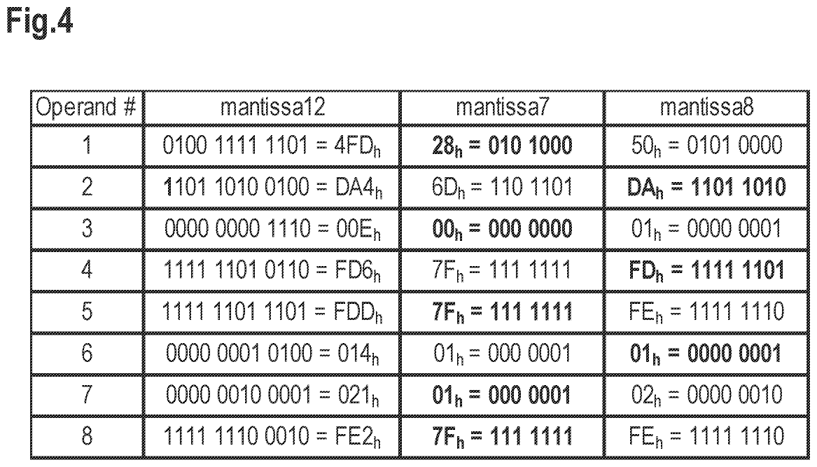

FIG. 4 shows a table comprising the values “mantissa12” (see column 8 of FIG. 3), “mantissa7” (see column 9 of FIG. 3) and “mantissa8” for the operands 1 to 8.

The value of the mantissa8 is determined similar to the value of the mantissa7, i.e.: The 8 MSBs of the mantissa12 value are taken and the 9th MSB of the mantissa12 value determines if a rounding is applied. Hence, if the 9th MSB is 1, the value 1 is added; if the 9th MSB is 0, nothing is added.

Hence, the 64-bit block of compressed data is determined by concatenating the bits of the common exponent (1Aₕ) and the bits of the mantissa7 with the bits of the mantissa8 (for the operands 2, 4 and 6) for the respective operands, which results in:

11010 0101000 11011010 0000000 11111101 1111111 00000001 0000001 1111111.

This representation can be re-sorted in 4-bit portions as follows

1101 0010 1000 1101 1010 0000 0001 1111

1011 1111 1100 0000 0100 0000 1111 1111,

which in hexadecimal notation corresponds to

D28D A01F BFC0 40FF.

This compressed representation efficiently uses all bits of a 64-bit block.

Further embodiments, alternatives and advantages:

In the example explained above, the common exponent is determined to be the largest of the exponents of the selected group of operands.

As an alternative, the common exponent may be pre-set or pre-configured. As another alternative, the common exponent may be determined based on a constant or offset which may be subtracted from the highest exponent of the set operands. With regard to the example above (see in particular the table of FIG. 3), a constant value of 5 may be subtracted from the highest exponent 1Aₕ, which results in 15ₕ to be used as the common exponent.

Hence, examples described herein relate to a compression approach for radar signals utilizing floating point representations in an efficient and improved manner by normalizing a selected group of operands to a common exponent and adjusting the mantissa according to the selected common exponent and according to a predefined precision.

The compression may be used in various domains of radar applications, e.g., with regard to operands used in a range, a Doppler and/or an antenna domain.

The compression allows for an efficient utilization of existing memory space or for applications that require less physical memory. This increases the flexibility with regard to radar applications, which may be implemented, e.g., in vehicles.

In one or more examples, the functions described herein may be implemented at least partially in hardware, such as specific hardware components or a processor. More generally, the techniques may be implemented in hardware, processors, software, firmware, or any combination thereof. If implemented in software, the functions may be stored on or transmitted over as one or more instructions or code on a computer-readable medium and executed by a hardware-based processing unit. Computer-readable media may include computer-readable storage media, which corresponds to a tangible medium such as data storage media, or communication media including any medium that facilitates transfer of a computer program from one place to another, e.g., according to a communication protocol. In this manner, computer-readable media generally may correspond to (1) tangible computer-readable storage media which is non-transitory or (2) a communication medium such as a signal or carrier wave. Data storage media may be any available media that can be accessed by one or more computers or one or more processors to retrieve instructions, code and/or data structures for implementation of the techniques described in this disclosure. A computer program product may include a computer-readable medium.

By way of example, and not limitation, such computer-readable storage media can comprise RAM, ROM, EEPROM, CD-ROM or other optical disk storage, magnetic disk storage, or other magnetic storage devices, flash memory, or any other medium that can be used to store desired program code in the form of instructions or data structures and that can be accessed by a computer. Also, any connection is properly termed a computer-readable medium, i.e., a computer-readable transmission medium. For example, if instructions are transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. It should be understood, however, that computer-readable storage media and data storage media do not include connections, carrier waves, signals, or other transient media, but are instead directed to non-transient, tangible storage media. Disk and disc, as used herein, includes compact disc (CD), laser disc, optical disc, digital versatile disc (DVD), floppy disk and Blu-ray disc where disks usually reproduce data magnetically, while discs reproduce data optically with lasers. Combinations of the above should also be included within the scope of computer-readable media.

Instructions may be executed by one or more processors, such as one or more central processing units (CPU), digital signal processors (DSPs), general purpose microprocessors, application specific integrated circuits (ASICs), field programmable logic arrays (FPGAs), or other equivalent integrated or discrete logic circuitry. Accordingly, the term “processor,” as used herein may refer to any of the foregoing structure or any other structure suitable for implementation of the techniques described herein. In addition, in some aspects, the functionality described herein may be provided within dedicated hardware and/or software modules configured for encoding and decoding, or incorporated in a combined codec. Also, the techniques could be fully implemented in one or more circuits or logic elements.

The techniques of this disclosure may be implemented in a wide variety of devices or apparatuses, including a wireless handset, an integrated circuit (IC) or a set of ICs (e.g., a chip set). Various components, modules, or units are described in this disclosure to emphasize functional aspects of devices configured to perform the disclosed techniques, but do not necessarily require realization by different hardware units. Rather, as described above, various units may be combined in a single hardware unit or provided by a collection of interoperative hardware units, including one or more processors as described above, in conjunction with suitable software and/or firmware.

Although various example embodiments of the disclosure have been disclosed, it will be apparent to those skilled in the art that various changes and modifications can be made which will achieve some of the advantages of the disclosure without departing from the spirit and scope of the disclosure. It will be obvious to those reasonably skilled in the art that other components performing the same functions may be suitably substituted. It should be mentioned that features explained with reference to a specific figure may be combined with features of other figures, even in those cases in which this has not explicitly been mentioned. Further, the methods of the disclosure may be achieved in either all software implementations, using the appropriate processor instructions, or in hybrid implementations that utilize a combination of hardware logic and software logic to achieve the same results. Such modifications to the inventive concept are intended to be covered by the appended claims.

1. A radar device comprising processing circuitry configured to:
select a set of operands comprising several operands from radar data, wherein each operand comprises a mantissa,
determine a common exponent for the operands of the selected set of operands,
normalize the operands based on the common exponent,
compress each operand by reducing a resolution of its mantissa,
store the common exponent and the compressed operands in a memory.

2. The device according to claim 1, wherein the operands are operands of radar data supplied by an FFT operation.

3. The device according to claim 1, wherein several sets of operands are processed until all operands of the radar data have been compressed and stored in the memory.

4. The device according to claim 1, wherein the set of operands is compressed to a predetermined block size.

5. The device according to claim 1, wherein the operands of the set of operands are floating-point numbers comprising a sign, an exponent and the mantissa.

6. The device according to claim 1, wherein the operands of the set of operands are compressed utilizing one resolution of the mantissa.

7. The device according to claim 1, wherein the operands of the set of operands are compressed utilizing at least two different resolutions provided by at least two mantissas of reduced size compared to resolution of the mantissa of the non-compressed operands.

8. The device according to claim 1, wherein the common exponent is determined based on the selected set of operands.

9. The device according to claim 8, wherein the common exponent is determined based on the largest exponent within the selected set of operands.

10. The device according to claim 8, wherein the common exponent is determined based on the selected set of operands and at least one additional value, offset or constant.

11. A method for processing radar signals, comprising:
selecting a set of operands comprising several operands from radar data, wherein each operand comprises a mantissa,
determining a common exponent for the operands of the selected set of operands,
normalizing the operands based on the common exponent,
compressing each operand by reducing a resolution of its mantissa,
storing the common exponent and compressed operands in a memory.

12. The method according to claim 11, wherein the operands are operands of radar data supplied by an FFT operation.

13. The method according to claim 11, wherein several sets of operands are processed until all operands of the radar data have been compressed and stored in the memory.

14. The method according to claim 11, wherein the set of operands is compressed to a predetermined block size.

15. The method according to claim 11, wherein the operands of the set of operands are floating-point numbers comprising a sign, an exponent and the mantissa.

16. The method according to claim 11, wherein the operands of the set of operands are compressed utilizing one resolution of the mantissa.

17. The method according to claim 11, wherein the operands of the set of operands are compressed utilizing at least two different resolutions provided by at least two mantissas of reduced size compared to resolution of the mantissa of the non-compressed operands.

18. The method according to claim 11, wherein the common exponent is determined based on the selected set of operands.

19. The method according to claim 18, wherein the common exponent is determined based on the largest exponent within the selected set of operands.

20. A computer program product directly loadable into a memory of a digital processing device, comprising software code portions for performing the acts of the method according to claim 11.
